(19) United States
(12) Patent Application Publication
(10) Pub. No.: US 2003/0062080 A1
(43) Pub. Date: Apr. 3, 2003

(54) Photoelectrochemical device

(75) Inventors: Masaharu Satoh, Tokyo (JP); Kentaro Nakahara, Tokyo (JP); Jiro Iriyama, Tokyo (JP); Shigeyuki Iwasa, Tokyo (JP); Yukiko Morioka, Tokyo (JP)

Correspondence Address: Paul J. Esatto, Jr., Scully, Scott, Murphy & Presser, 400 Garaden City Plaza, Garden City, NY, 11530, US

(73) Assignee: NEC Corporation, Tokyo (JP)

(21) Appl. No.: 10/253,085

(22) Filed: Sep. 24, 2002

(30) Foreign Application Priority Data
Sep. 26, 2001 (JP) 293959/2001

(51) Int. Cl. H01L 31/00

(52) U.S. Cl. 136/256; 136/263; 429/111

(57) ABSTRACT

A photoelectrochemical device having new construction, which enables a large stable photoelectric conversion element, an energy storage element and the like to be manufactured at low cost. The photoelectrochemical device is provided with an organic compound which generates a radical compound through electrochemical oxidation reaction and/or reduction reaction, and a semiconductor arranged in contact with the organic compound. Preferably, the generated radical compound has a spin density of 10²⁰ spins/g or more. In addition, it is preferable to use as the organic compound an organic polymer compound with the number average molecular weight ranging from 10³ to 10⁷. More specifically, the photoelectrochemical device comprises a semiconductive electrode having a semiconducting layer, an organic compound layer that is in contact with the semiconductive electrode and generates a radical compound through electrochemical oxidation reaction and/or reduction reaction, a counter electrode opposing to the semiconductive electrode, and an electrolyte layer arranged between the organic compound layer and counter electrode. In the photoelectrochemical device, irradiating light on the semiconductor effects an electrical, optical, or chemical change through electrochemical oxidation reaction and/or reduction reaction.

### FIELD OF THE INVENTION

The present invention relates to a photoelectrochemical device, more particularly to a photoelectrochemical device provided with a semiconductor and an organic compound generating a radical compound in process of at least electrochemical oxidation reaction or reduction reaction, such as a photoelectric conversion element, an energy storage element, an information recording element and the like.

### BACKGROUND OF THE INVENTION

Photoelectric conversion elements for converting photo energy into electric energy and energy storage elements for storing the electric energy are used for various purposes in the form of solar cells, memory devices, etc.

For example, solar cells are widely known as the photoelectric conversion element. The solar cell is basically constructed from semiconductors forming a p-n junction. In the solar cell, charge carriers (electrons/positive holes) generated or excited at a p-n junction region by solar radiation diffuse and are transported through a semiconductor. When reaching an internal electric field region, electrons of the charge carriers are driven to the electrode on n-side and holes are driven to the electrode on p-side under the influence of the internal electric field. The solar cell provides electrical output by means of externally connecting the electrodes on both sides of the p-n junction. Imaging devices, memory devices, etc. have been developed from the solar cell or photo diode comprised of the p-n junction with a charge transfer element.

As the solar cell, there have been proposed photoelectrochemical cells utilizing organic compound-based dyes. An example of such cells is described in literature: Michael Grätzel et al., “Ultrafast Electron Injection: Implications for a Photoelectrochemical Cell Utilizing an Anthocyanin Dye-Sensitized TiO₂ Nanocrystalline Electrode,” J. Phys. Chem. B 1997, 101, 9342. The solar cell contains a pair of opposite electrodes (an anode and a cathode) and an electrolyte in between them. The cathode is made of a glass plate having a transparent conductive layer of light-transmitting tin dioxide (SnO₂) on its surface. The electrolyte includes iodide ion couples having different oxidation states as a mediator. The anode is made of a glass plate having on its surface the SnO₂ layer like the one above and also a semiconducting titanium dioxide (TiO₂) layer thereon. The TiO₂ layer is formed with a TiO₂ semiconductor consisting of nanocrystalline particles, to the surface of which anthocyanin dyes are attached. When the interface between the TiO₂ nanocrystalline layer and dyes is irradiated, the mediator undergoes oxidation within the electrolyte. That is, three iodide ions (I⁻) eject two electrons, resulting in triiodide ions (I₃³¹ ) of high oxidation degree. The triiodide ions (I₃⁻) are driven to the cathode by electric field, and obtain two electrons to be deoxidized into the iodide ions (I₃⁻). On this occasion, the photoexcited electrons that exceed the Fermi level of the titanium dioxide enter the conduction band. The electrons are then transported through the TiO₂ nanocrystalline layer and collected by the transparent conductive layer. Thus, this type of wet cell converts solar energy into electric energy.

As for energy storage elements, there have been utilized secondary cells or storage batteries, in which alkali metal ions such as lithium ions serve as charge carriers, providing electrical output through electrochemical reaction to the electron transfer (oxidation-reduction reaction). Lithium ion batteries are among the secondary cells, and especially adopted in a variety of electronic equipment as stable high-energy density batteries with a great capacitance.

However, it is difficult to manufacture large photoelectric conversion elements such as the solar cell at a low cost due to its complicated semiconductor manufacturing process. Moreover, in order to store the electric energy generated by the photoelectric conversion element, it is necessary to use an additional energy storage element such as the secondary cell or capacitor therewith, which presents constitutional drawbacks. Furthermore, the above-mentioned wet solar cell produces low photoelectric conversion efficiency since most of the incident light passes through the semiconducting layer.

Besides, the energy storage element such as the secondary cell, etc. is charged by passing a current from an external source through it, and incapable of generating electricity. Therefore, the energy storage element also needs another storage element such as the secondary cell, capacitor or the like for storing the electric energy generated by the photoelectric conversion element. In addition, semiconductor capacitors, which include n-type semiconductors each having silver electrodes on both sides, have been known as the energy storage element formed from semiconductors. The semiconductor capacitors have a problem that the conservable energy amount is a little.

### SUMMARY OF THE INVENTION

It is therefore an object of the present invention to provide a photoelectrochemical device having new construction so that a large stable photoelectric conversion element, an energy storage element, etc. can be manufactured at low cost.

It is another object of the present invention to provide a photoelectrochemical device integrally including an energy storage element for storing the electric energy generated by the photoelectric conversion element.

In accordance with the first aspect of the present invention, to achieve the above object, there is provided a photoelectrochemical device having an organic compound generating a radical compound in process of at least electrochemical oxidation reaction or reduction reaction, and a semiconductor in contact with the organic compound.

The photoelectrochemical device is characterized in that the organic compound generates the radical compound through at least electrochemical oxidation reaction or reduction reaction, and with the combination of the organic compound and semiconductor, charge carriers (electrons/holes) generated by irradiating the semiconductor are involved in redox reaction of the organic compound and cause the generation/disappearance of the radical compound due to radical reaction. In the photoelectrochemical device of the present invention, the radical compound and organic compound that generates the radical compound serve as a redox pair or a redox couple, which increases the rate of reaction to light irradiation of the semiconductor. Besides, since the radical compound and organic compound are characteristically generated/disappear through electrochemical oxidation reaction or reduction reaction, the photoelectrochemical device is provided with excellent stability and reproducibility. Additionally, the photoelectrochemical device is simply constructed, and does not need the complicated semiconductor manufacturing process differently from conventional ones. Consequently, it is possible to manufacture a large stable photoelectrochemical device at low cost.

In accordance with the second aspect of the present invention, in the first aspect, the generated radical compound has a spin density of 10²⁰ spins/g or more.

The radical compound having such high spin density facilitates the radical reaction. As a result, the photoelectrochemical device is provided with excellent stability and high photoelectric conversion efficiency. In addition, with the use of the organic compound that generates the radical compound having high spin density, it is possible to realize a photoelectrochemical device with great capacitance.

In accordance with the third aspect of the present invention, in the first or second aspect, the radical compound is in a solid state at room temperature.

In the solid state, the radical compound can maintain stable contact with the semiconductor without undergoing transmutation and deterioration due to a side reaction caused by other chemicals, fusion, and diffusion. Accordingly, the photoelectrochemical device is provided with excellent stability.

In accordance with the fourth aspect of the present invention, in one of the first to third aspects, while there is no special limitation imposed upon the organic compound as long as it generates the radical compound through at least electrochemical oxidation reaction or reduction reaction, an organic polymer compound is preferable for its stability and usability. An organic polymer compound with the number average molecular weight of 10³ to 10⁷ is especially preferable.

Such organic polymer compound enables the stable use of the radical compound, which is fast in reaction rate but uncontrollable due to its instability and therefore not easily applicable to photoelectric conversion elements and energy storage elements in general. As a result, the photoelectrochemical device can achieve excellent stability and improved reaction rate.

In accordance with the fifth aspect of the present invention, there is provided a photoelectrochemical device comprising a semiconductive electrode having a semiconducting layer, an organic compound layer that is in contact with the semiconductive electrode and generates a radical compound in process of at least electrochemical oxidation reaction or reduction reaction, a counter electrode opposing to the semiconductive electrode, and an electrolyte layer arranged between the organic compound layer and counter electrode.

The organic compound layer and the semiconducting layer in contact form a Schottky junction, which makes potential gradient in the conduction band and valence band of the semiconductor. Consequently, electrons and holes are driven to the surface of the semiconducting layer by the potential gradient and involved in redox reaction of the organic compound. The electrons and holes are then transported through short-circuit formed between the semiconductive electrode and counter electrode, thus providing electrical output in the form of electrical signals or electric energy.

### BRIEF DESCRIPTION OF THE DRAWINGS

The objects and features of the present invention will become more apparent from the consideration of the following detailed description taken in conjunction with the accompanying drawings in which:

FIG. 1 is a cross sectional view showing an example of the configuration of a photoelectrochemical device according to the present invention;

FIG. 2 is a cross sectional view showing another example of the configuration of a photoelectrochemical device according to the present invention; and

FIG. 3 is a perspective view showing the primal configuration of the photoelectrochemical device depicted in FIG. 2.

### DESCRIPTION OF THE PREFERRED EMBODIMENTS

Referring now to the drawings, a description of preferred embodiments of the present invention will be given.

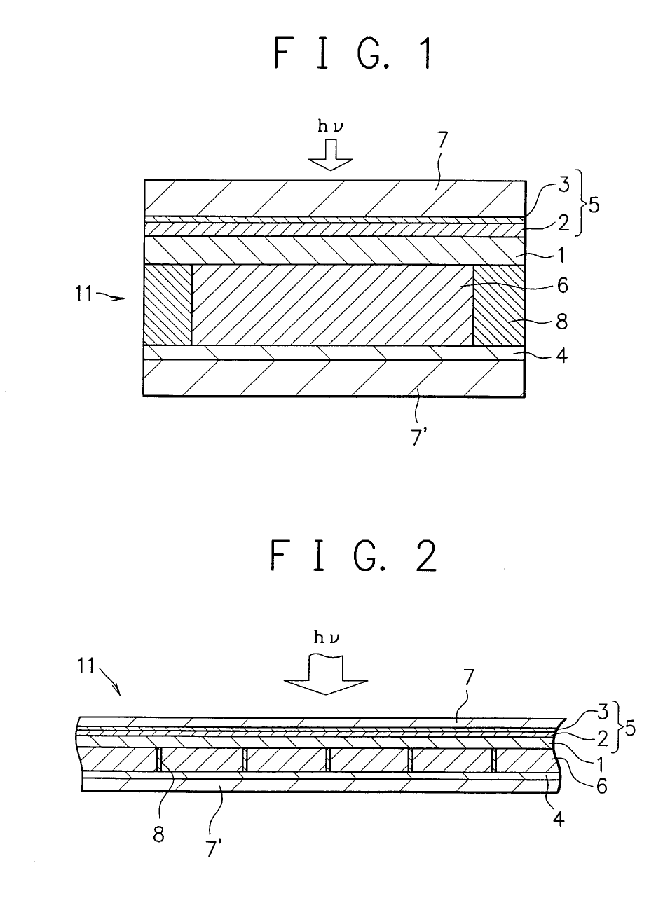

FIG. 1 is a cross sectional view showing an example of the configuration of a photoelectrochemical device according to the present invention. As can be seen in FIG. 1, for example, the photoelectrochemical device 11 comprises an organic compound layer 1 and a semiconducting layer 2. The organic compound layer 1 consists of an organic compound that generates a radical compound through oxidation-reduction reaction in which the electron transfer is proceeded by irradiated light or impressed voltage. The semiconducting layer 2 consists of a semiconductor, and arranged in contact with the organic compound layer 1. The photoelectrochemical device 11 of the present invention is characterized by the use of the organic compound, which generates a radical compound through at least electrochemical oxidation reaction or reduction reaction. The electrochemical reactions between charge carriers (electrons and holes) generated by irradiating the semiconductor and the organic compound produce electric charge, and thus inducing charge transfer. With the use of the radical compound having high-reaction rate as one of the redox pair, the photoelectrochemical device 11 achieves excellent stability and improved reaction rate. Thus, it is possible to realize fast-reaction stable photoelectric conversion elements, energy storage elements for storing charge, and the like.

In the following, the principles of the photoelectrochemical device 11 will be explained with reference to FIG. 1.

As is described above, the photoelectrochemical device 11 comprises the organic compound layer 1 and the semiconducting layer 2 in layers. The semiconducting layer 2 is provided with a transparent conductive layer 3 on its surface if required, and forms a semiconductive electrode 5. The photoelectrochemical device 11 further comprises an electrolyte layer 6 if required and a counter electrode 4. The counter electrode 4 is set on the surface of the organic compound layer 1 or the electrolyte layer 6 contacting with the organic compound layer 1 so as to be opposed to the semiconductive electrode 5. In this construction of the photoelectrochemical device 11, an organic compound that generates a radical compound as one of the redox pair is in contact with a semiconductor. The organic compound-semiconductor contact forms a Schottky junction, which makes potential gradient in the conduction band and valence band of the semiconductor. Having been driven to the surface of the semiconductor by the potential gradient, electrons and holes are involved in the redox reaction of the organic compound and cause the generation/disappearance of the radical compound due to radical reaction. The electrons and holes are then transported through short-circuit formed between the semiconductive electrode 5 and counter electrode 4, and thus providing electrical output in the form of electrical signals or electric energy.

According to the present invention, the electrons or holes originating in the semiconductor act on the organic compound that (re)generates the radical compound through at least electrochemical oxidation reaction or reduction reaction. Consequently, the organic compound undergoes chemical change from a non-radical compound to a radical compound and vice versa or a radical compound to another radical compound through oxidation reaction and/or reduction reaction. In the photoelectrochemical device of the present invention, the radical compound and non-radical compound are stabilized, and energy outputs of photoelectric conversion are obtained through electrochemical state change in the reaction product, namely, the radical compound and its redox reactant. Thus, the photoelectrochemical device can be favorably utilized as a photochemical conversion element, a photochemical cell and the like. Besides, with the combination of such organic compound and semiconductor, electrons and holes generated by irradiating the semiconductor are involved in redox reaction of the organic compound and induce the generation/disappearance of the radical compound due to radical reaction. In addition, the reactive radical compound and organic compound that (re)generates the radical compound serve as a redox pair, which increases the rate of reaction to light irradiation of the semiconductor. Furthermore, since the radical compound and organic compound are characteristically generated/disappear through electrochemical oxidation reaction or reduction reaction, the photoelectrochemical device is provided with excellent stability and reproducibility.

According to the present invention, the radical compound is defined as a chemical species having an unpaired electron (an electron that is not part of a pair), that is, a compound having free radicals. In the radical compound, spin angular momentum is not zero, and various magnetic properties such as paramagnetism, etc. are exhibited. The existence of the unpaired electrons possessed by the radical compound can be observed by measuring or analyzing electron spin resonance spectrum (hereinafter referred to as “ESR spectrum”) and the like. Incidentally, an organic component whose electrons are delocalized is not regarded as the radical component even when a signal is found in the ESR spectrum. Examples of the components having such delocalized electrons include conducting polymers that form soliton or polaron. The conducting polymers have a low spin density of, normally, 10¹⁹ spins/g or less.

The radical reaction means a chemical reaction in which the free radical is concerned. According to the present invention, the radical reaction is specifically defined as reaction in the process of at least electrochemical oxidation reaction or reduction reaction, in which a radical compound is generated from a non-radical compound, the generated radical compound is converted into a non-radical compound, or a radical compound is converted into another radical compound.

The electrochemical oxidation reaction or reduction reaction generally means reaction involving the electron transfer promoted by irradiating light or applying voltage to chemicals having an electrical contact with an electrode arranged in electrolyte. Examples of the electrochemical oxidation-reduction reactions include a reaction that proceeds on the occasion of battery charging/discharging.

In order to provide the photoelectrochemical device with a great open circuit voltage and stability, it is preferable to select: (a) an organic compound capable of generating a stable radical compound; (b) a semiconductor having a Fermi level that creates a large band gap with the redox level of the organic compound and; (c) a low redox level (highly oxidative) electrolyte if an electrolyte is included.

Next, each component comprised in the photoelectrochemical device will be described in detail with reference to the above-mentioned items (a) to (c).

[Organic Compound]

The organic compound used in the photoelectrochemical device of the present invention is a compound that generates a radical compound through at least electrochemical oxidation reaction or reduction reaction. While there is no special limitation imposed upon the kind of the radical compound, a stable one is preferable. The organic compound should be selected in consideration of the effect of the present invention brought about according to the action of the radical compound, and the processability of the formed organic compound layer.

It is especially preferable that the organic compound includes structural unit shown by formula (1) and/or (2).

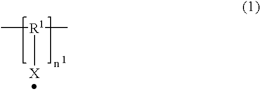

In formula (1): substituent R¹ indicates one selected from substitutive or non-substitutive C₂-C₃₀ alkylene group, C₂-C₃₀ alkenylene group and C₄-C₃₀ arylene group; X is one selected from oxyradical group, nitroxylradical group, sulfurradical group, hydraziylradical group, carbonradical group and boronradical group; n¹ is an integer more than 1.

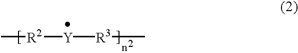

In formula (2): substituents R² and R³ are mutually independent, each indicating one selected from substitutive or non-substitutive C₂-C₃₀ alkylene group, C₂-C₃₀ alkenylene group and C₄-C₃₀ arylene group; Y is one selected from nitroxylradical group, sulfurradical group, hydraziylradical group and carbonradical group; n² is an integer more than 1.

Examples of radical compound in formulas (1) and (2) include oxyradical compounds, nitroxylradical compounds, carbonradical compounds, nitrogenradical compounds, boronradical compounds, and sulfurradical compounds. The number average molecular weight of 10³ to 10⁷, especially 10³ to 10⁵ is preferable for the organic compound that generates a radical compound having structural unit shown by formula (1) and/or (2).

As concrete examples of the oxyradical compounds, there are aryloxyradical compounds as shown by formulas (3) and (4) below, and semiquinoneradical compounds as shown by formula (5).

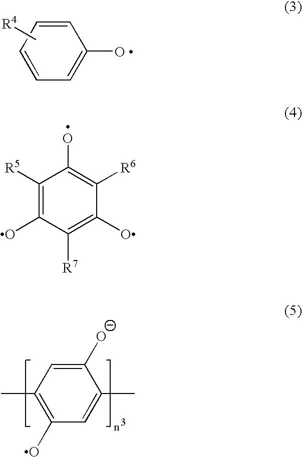

In formulas (3) to (5): substituents R⁴ to R⁷ are mutually independent, each indicating one selected from proton, substitutive or non-substitutive, aliphatic or aromatic C₁-C₃₀ hydrocarbon group, halogen group, hydroxyl group, nitro group, nitroso group, cyano group, alkoxy group, aryloxy group, and acyl group. In formula (5), n³ is an integer more than 1. The number average molecular weight of 10³ to 10⁷ is preferable for the organic compound that generates a radical compound having structural unit shown by one of formulas (3) to (5).

As concrete examples of the nitroxylradical compounds, there are radical compounds having a piperidinoxy ring as shown by formula (6) below, radical compounds having a pyrrolidinoxy ring as shown by formula (7), radical compounds having a pyrrolinoxy ring as shown by formula (8), and radical compounds having a nitronylnitroxid structure as shown by formula (9).

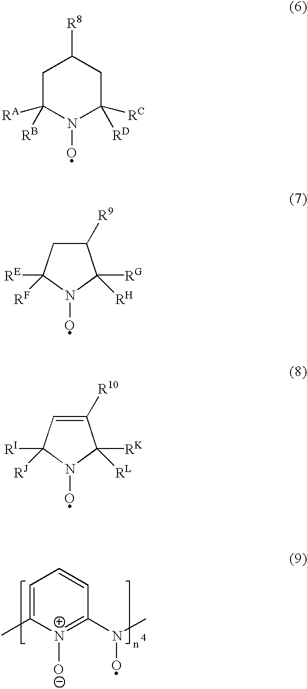

In formulas (6) to (8), substituents R⁸ to R¹⁰ and R^{A} to R^{L} include the same contents as the aforementioned R⁴ to R⁷ in formulas (3) to (5) do. In formula (9), n⁴ is an integer more than 1. The number average molecular weight of 10³ to 10⁷ is preferable for the organic compound that generates a radical compound having structural unit expressed by one of formulas (6) to (9).

As concrete examples of the nitroxylradical compounds, there are radical compounds having a trivalent hydrazyl group as shown by formula (10) below, radical compounds having a trivalent ferredazyl group as shown by formula (11), and radical compounds having a aminotriazine structure as shown by formula (12).

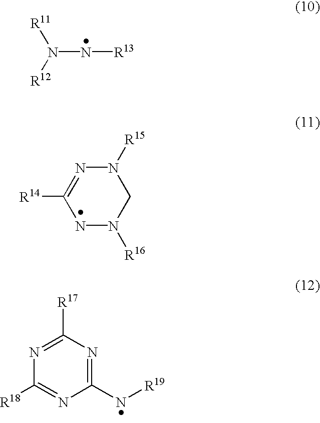

In formulas (10) to (12), substituents R¹¹ to R¹⁹ include the same contents as the aforementioned R⁴ to R⁷ in formulas (3) to (5) do. The number average molecular weight of 10³ to 10⁷ is preferable for the organic compound that generates a radical compound having structural unit expressed by one of formulas (10) to (12). An organic polymer compound with the number average molecular weight of 10³ to 10⁷ is especially preferable to generate the radical compound having structural unit expressed by one of formulas (6) to (9). The organic polymer compound having such number average molecular weight provides excellent stability, and can be stably used for photoelectric conversion elements and energy storage elements. Consequently, the photoelectrochemical device can achieve excellent stability and improved reaction rate.

Among the above-mentioned organic compounds, an organic compound that is in a solid state at room temperature (25±35° C.) is particularly preferable to obtain a solid radical compound at room temperature. In the solid state, the radical compound can maintain stable contact with the semiconductor without undergoing transmutation and deterioration due to a side reaction caused by other chemicals, fusion, and diffusion. Accordingly, the photoelectrochemical device is provided with excellent stability.

Besides, according to the present invention, the radical compound, which is generated through at least electrochemical oxidation reaction or reduction reaction, has preferably, but not necessarily, a spin density of 10²⁰ spins/g or more. The density levels of 10²⁰ to 10²³ spins/g are particularly preferable as the spin density of the radical compound for realizing the photoelectrochemical device with higher photoelectric conversion efficiency and excellent stability. The radical compound having such high spin density facilitates the radical reaction. Accordingly, the photoelectrochemical device is provided with high photoelectric conversion efficiency and great capacitance. Incidentally, with the use of the radical compound having a spin density less than 10²⁰ spins/g, the photoelectric conversion efficiency shows a downward tendency. When used for storage batteries, the radical compound with a spin density of this level decrease the capacitance of the batteries.

In addition, charge carriers (electrons/holes) photogenerated in the semiconductor by irradiating light act on the organic compound, resulting in the generation/disappearance of the radical compound. In the photoelectrochemical device of the present invention, a reactive radical compound and an organic compound that generates the radical compound serve as a redox pair, which increases the rate of reaction to light irradiation of the semiconductor. Moreover, the photoelectrochemical device is provided with excellent stability and reproducibility

The organic compound layer 1 may be formed directly out of the above-described organic compound. Alternatively, the layer 1 may be made by means of dissolving it in a solvent and volatilizing the solvent after coating. In this case, one or various additives in combination may be used with the solvent. As the solvent, a common organic solvent is employed. Examples of the solvent include, but are not limited to: basic solvents such as dimethylsulfoxide, dimethylformamide, N-methylpyrrolidone, propylene carbonate, diethyl carbonate, dimethyl carbonate, γ-butyrolactone, etc.; nonaqueous solvents such as acetonitrile, tetrahydrofuran, nitrobenzene, acetone, etc.; and protonic solvents such as methyl alcohol, ethyl alcohol, etc. On the other hand, examples of the additives include: resin such as polyethylene, polyvinylidene fluoride and others acting as a binder or a viscosity regulator; and carbon powder, etc. acting as a collector. There is also no special limitation imposed upon the coating method. Decisions on the solvent, the compounding ratio of organic compound thereto, the additive, and the amount thereof, etc. are arbitrarily made in consideration of the type of the photoelectrochemical device and its quality requirement as well as the manufacturability during the production process.

[Semiconductor]

The semiconducting layer 2 comprised in the photoelectrochemical device of the present invention is a photo-semiconductor that generates electrons and holes when irradiated. The semiconductor consists of a matter that exhibits a conductivity midway between that of metals and insulators, typically 10⁻¹⁰ to 10³ siemens per centimeter (S/cm).

The semiconductor may be made of, although not necessarily, various intrinsic semiconductors or impurity semiconductors. Examples in point include: elemental semiconductors made of elements belonging to IV group (in periodic table) such as Si and Ge; compound semiconductors made of III-VI compounds such as GaAs and InP, or II-V compounds such as ZnTe; oxide semiconductors made of Cd, Zn, In, Si or the like; perovskite-type semiconductors made of SrTiO₃, CaTiO₃ or the like; transparent conductive semiconductors made of indium/tin oxide or the like, which can be utilized as the transparent conductive layer 3; photo-semiconductive polymers such as transition metal chalcogenide, polyacetylene, polythiophene or the like; and photo-semiconductive organic complexes such as tetracyanoquinodimetane-tetrathiafulvalene complex or the like.

In order to provide the photoelectrochemical device with a great electromotive force and stability, it is preferable to use a semiconductor having a Fermi level that creates a wide band gap with the redox level of the organic compound layer 1 consisting of the above-mentioned organic compound in which the electrochemical oxidation reaction or reduction reaction occurs. The use of such semiconductor reinforces the photovoltaic power of the photoelectrochemical device, and thus realizing the photoelectrochemical device with a great electromotive force.

The semiconductor may be of n-type or p-type.

Additionally, it is possible to use dyes, etc. together with the semiconductor as a photo sensitizer, which are commonly employed in conventional dye-sensitized photoelectric conversion elements. Examples of dyes include: ruthenic complex dyes, osmic complex dyes, zincic complex dyes, organic dyes and the like. The amount of the dyes may be arbitrarily adjusted.

In the photoelectrochemical device of the present invention, the organic compound layer 1 and semiconducting layer 2 in contact form a Schottky junction, which originates potential gradient in the conduction band and valence band of the semiconductor. Consequently, electrons and holes are driven to the surface of the semiconducting layer 2 by the potential gradient and involved in the redox reaction of the organic compound that generates the radical compound through at least electrochemical oxidation reaction or reduction reaction. The electrons and holes are then transported through short-circuit formed between the semiconductive electrode 5 and counter electrode 4, and provide electrical output in the form of electrical signals or electric energy.

[Other Components]

As shown in FIGS. 1 to 3, in the construction of the photoelectrochemical device 11, the semiconducting layer 2 is provided with the transparent conductive layer 3 on its surface if necessary, and forms the semiconductive electrode 5. Further, the counter electrode 4 is set on the surface of the organic compound layer 1 or the electrolyte layer 6 that is provided, if necessary, in contact with the organic compound layer 1.

The transparent conductive layer 3 is only required not to block the irradiating light on the semiconducting layer 2 and to have electric conductivity so that electric energy can be outputted. Concretely, it is preferable to use a transparent conductive film excelling in light transmissivity, which is made of, for example, indium/tin oxide, tin oxide, indium oxide or the like. The transparent conductive layer 3 is formed on a substrate 7 made of glass or polymer sheet, etc. that excels in light transmissivity. The semiconducting layer 2 is arranged thereon, and thereby forming the semiconductive electrode 5. The organic compound layer 1 is stacked on the semiconductive electrode 5.

The counter electrode 4 is made of electrically conductive material. Examples of the material include, but not limited to, lithium superimposed copper foil, platinum plate and the like. The counter electrode 4 is formed on a substrate 7′ made of glass or polymer sheet, etc. so as to be opposed to the semiconductive electrode 5 with the organic compound layer 1 therebetween.

The electrolyte layer 6 may be provided in between the organic compound layer 1 and the counter electrode 4 if required for charge carrier-mediated transport between an anode and a cathode. Generally, the electrolyte layer 6 is made of an electrolyte that exhibits an ionic conductivity of 10⁻⁵ to 10⁻¹ S/cm at room temperature. As the electrolyte, an electrolytic solution obtained by dissolving electrolytic salt in a solvent or a solid electrolyte consisting of high polymer compounds that include electrolytic salt may be used.

As the electrolytic salt, conventionally known materials such as LiPF₆, LiClO₄, LiBF₄, LiCF₃SO₃, Li (CF₃SO₂)₂N, Li(C₂F₅SO₂)₂N, Li(CF₃SO₂)₃C, Li(C₂F₅SO₂)₃C or the like can be used.

As the solvent for dissolving the electrolytic salt, an organic solvent is used. Examples of the organic solvent include: ethylene carbonate, propylene carbonate, dimethyl carbonate, diethyl carbonate, methyl ethyl carbonate, γ-butyrolactone, tetrahydrofuran, dioxolane, sulfolane, dimethylformamide, dimethylacetamide, N-methyl-2-pyrrolidone, and the like. The mixture of two or more of these may be used as the mixed solvent.

Besides, examples of the high polymer compound composing the solid electrolyte include: vinylidene fluoride-type copolymer such as poly vinylidene fluoride, vinylidene fluoride-hexafluoropropylene copolymer, vinylidene fluoride-ethylene copolymer, vinylidene fluoride-monofluoroethylene copolymer, vinylidene fluoride-trifluoroethylene copolymer, vinylidene fluoride-tetrafluoroethylene copolymer, vinylidene fluoride-hexafluoropropylene-tetrafluoroethylene ternary copolymer; acrylonitrile-type copolymer such as acrylonitrile-methylmethacrylate copolymer, acrylonitrile-methylacrylate copolymer, acrylonitrile-ethylmethacrylate copolymer, acrylonitrile-ethylacrylate copolymer, acrylonitrile-methacrylic acid copolymer, acrylonitrile-acrylic acid copolymer, acrylonitrile-vinyl acetate copolymer; polyethylene oxide, ethylene oxide-propylene oxide copolymer, and copolymer of acrylate or methacrylate formation of them. The high polymer compound may be used directory, or gelled by adding electrolysis solution therein.

[Photoelectrochemical Device]

The photoelectrochemical device 11 of the present invention is a device in which electrons and holes photogenerated by irradiating the semiconductor interact with the organic compound to induce oxidation-reduction reaction. The photoelectrochemical device 11 is characterized in that the organic compound generates the radical compound through at least electrochemical oxidation reaction or reduction reaction.

With this construction, the photoelectrochemical device 11 of the present invention can be used as a various types of photoelectrochemical devices such as a memory element, a display element, a photoelectric conversion element, a photosensor, a solar cell, a solar storage battery, a transistor, etc. according to the combination of the semiconductor, counter electrode and the like.

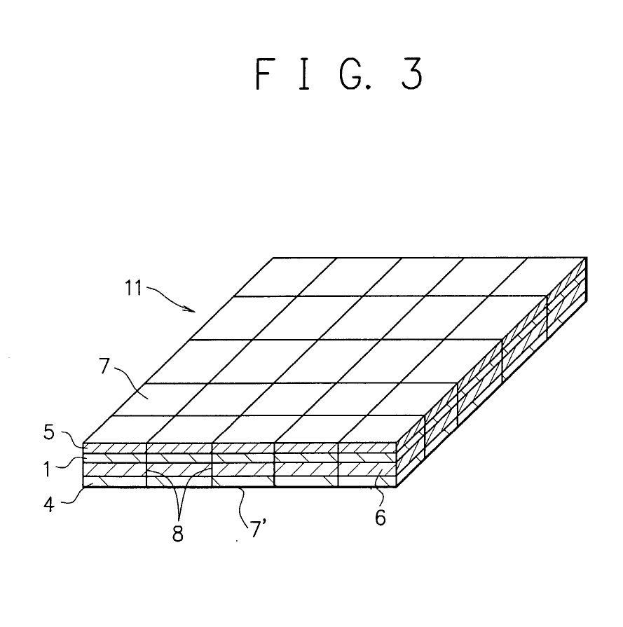

The photoelectrochemical device 11 basically comprises at least an organic compound and a semiconductor in layers as can be seen in FIGS. 1 to 3. Other components are arbitrarily added to the basic construction depending on the types of photoelectrochemical devices. With reference to FIGS. 1 to 3 showing concrete examples of the photoelectrochemical device 11, the semiconducting layer 2 is provided with the transparent conductive layer 3 on its surface, and thus forming the semiconductive electrode 5. On the semiconductive electrode 5, there is provided the substrate 7. The electrolyte layer 6, counter electrode 4, and substrate 7′ are arranged in layers on the surface of the organic compound layer 1 in this order. A spacer 8 is provided at each side of the electrolyte layer 6. The semiconductive electrode 5 may be formed in a matrix as shown in FIGS. 2 and 3.

In the following, a specific description will be given of examples of photoelectrochemical devices.

[Memory Element]

The memory element is an element for storing information in any physical state. The memory element made of the photoelectrochemical device 11 of the present invention takes advantage of the oxidation-reduction reaction in the organic compound layer 1 that generates the radical compound. The radical compound or non-radical compound is generated by means of, for example, irradiating the light on the semiconducting layer 2 while applying voltage to interelectrode between the semiconductive electrode 5 and counter electrode 4. The radical or non-radical compound is stored in an electrochemical state.

Consequently, information is written into the memory element through the, generation of the radical or non-radical compound. On the other hand, the information is read out of the memory device by means of detecting the spin density of the radical compound in the organic compound and discriminating the hues, reflectances, etc. of the organic compound layer 1 including the generated radical or non-radical compound.

For example, in the case of the memory element provided with the construction shown in FIG. 1, the current flow produced as a result of applying a voltage to interelectrode between the semiconductive electrode 5 and counter electrode 4 is little when the applied voltage is lower than the bath voltage (oxidation-reduction potential) of each electrode. However, electrons and holes photogenerated by irradiating the semiconducting layer 2 interact with the organic compound layer 1 to induce oxidation-reduction reaction. Thus, the organic compound layer 1 generates the radical or non-radical compound through at least electrochemical oxidation reaction or reduction reaction, and thereby writing task is performed. Besides, changes in state of the organic compound layer 1 that includes the generated radical or non-radical compound is detected by discriminating its characteristics such as spin density, hue, reflectance, etc., and thus stored information is read out.

[Display Element]

The construction of the display element is similar to that of the memory element. In the construction of the display element, the semiconductive electrode 5 and counter electrode 4 are arranged in a matrix as shown in FIGS. 2 and 3, and a voltage is applied only to specific parts while irradiating the light all over the electrodes 4 and/or 5. As a result, the aforementioned electrochemical reaction occurs in the specific parts of the organic compound layer 1. Accordingly, the specific parts change in hue and reflectance, and thus carrying out display function.

Photoelectric Conversion Element, Photosensor, and Solar Cell

The photoelectric conversion element such as a photosensor and a solar cell basically comprises at least the organic compound layer 1 and the semiconducting layer 2 in layers as shown in FIG. 1. Other components are arbitrarily added to the basic construction depending on the types of devices. More specifically, the semiconducting layer 2 is provided with the transparent conductive layer 3 on its surface, and forms the semiconductive electrode 5. On the semiconductive electrode 5, there is provided the substrate 7. The electrolyte layer 6, counter electrode 4, and substrate 7′ are arranged in layers on the surface of the organic compound layer 1 in this order. A spacer 8 is provided at each side of the electrolyte layer 6 as shown in FIG. 1.

With this construction, electrons and holes are photogenerated in the semiconductor by means of electrical connection between the semiconductive electrode 5 and counter electrode 4, and light irradiation. The electrons or holes interact with the organic compound layer 1 that generates the radical or non-radical compound through at least electrochemical oxidation reaction or reduction reaction to induce oxidation-reduction reaction. The photoelectric conversion element such as a photosensor and a solar cell is realized by the electrical output obtained at this point.

[Energy Storage Element]

The construction of the energy storage element such as solar storage battery or the like is similar to that of the photoelectric conversion element, etc. In the construction of the energy storage element, the semiconductive electrode 5 and counter electrode 4 are connected to each other via a rectifier. Electrons and holes are photogenerated in the semiconductor due to the electrical connection and light irradiation. The electrons or holes interact with the organic compound layer 1 and induce oxidation-reduction reaction, which (re)generates the radical or non-radical compound.

On this occasion, if current runs in the opposite direction of initial current flow, the oxidized/reduced organic compound reverts to type. However, the rectifier prevents the return of the oxidized/reduced organic compound, and thereby photo energy can be stored in the form of chemicals. With this construction, the energy storage element can simultaneously perform power generation with light and charge of electricity.

Incidentally, according to the present invention, the radical compound may be directly used as electrode active material to construct a battery. Additionally, it is possible to employ a non-radical compound that is converted into a radical compound in either process of charge or discharge as electrode active material to construct a battery.

In the following, preferred examples of the present invention will be described in detail.

### EXAMPLE 1

First, a transparent conductive indium/tin oxide (ITO) film of 0.01 μm in thickness was deposited as the semiconducting layer 2 on the substrate 7 of 0.8 mm thick glass plate by means of sputtering, and thus forming the semiconductive electrode 5. Subsequently, the organic compound layer 1 of 1 μm in thickness was formed on the semiconductive electrode 5 by means of spreading thereon a solution made by dissolving a radical compound consisting of gallubinoxylradical (represented by formula 13 below) in tetrahydrofuran in a concentration of 20 wt. %. This operation was carried out under an atmosphere of argon gas in a dry box that is provided with gas purification equipment. The spin density of the organic compound layer 1 measured by ESR spectrum was 1.2×10²¹ spins/g at that time.

On the organic compound layer 1, the electrolyte layer 6 of 10 μm in thickness was then formed with a gel electrolyte film, which consisted of vinylidene fluoride-hexafluoropropylene copolymer swelling in a mixed solvent of ethylene carbonate and diethyl carbonate (in a mass ratio of 1 to 1) including 1M (mol/1) of LiPF₆.

After that, an lithium superimposed copper foil of 25 μm in thickness was stacked as the counter electrode 4 on the electrolyte layer 6, and pressure was brought to bear thereon. Thus, there was obtained a photoelectrochemical device provided with an organic compound layer including gallubinoxylradical.

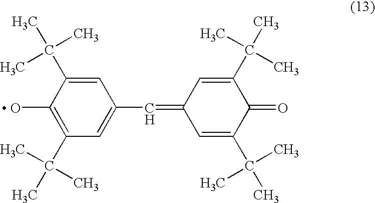

With the photoelectrochemical device obtained as above, in the case of sweeping the potential of the semiconductive electrode 5 as opposed to a lithium electrode, which was used as a reference electrode (the same applies to the following), in the range of 0 to 1.8V at the sweep rate of 100 mV/sec, the electric current was 0.1 mA/cm² or less at every potential. Next, when the potential was swept while irradiating tungsten halogen light of 100 mW/cm² on the semiconductive electrode 5, a largest current flow was observed at about 1.5V. The current reached a maximum strength of 2 mA/cm². This result confirmed that the photoelectrochemical device was able to sense the presence of irradiating light.

### EXAMPLE 2

In this example, a photoelectrochemical device was manufactured in the same manner as described previously in example 1 but for the use of a radical compound consisting of 2,2,6,6-tetramethylpiperidinoxiradical (represented by formula 14 below) instead of gallubinoxylradical. Accordingly, there was obtained a photoelectrochemical device provided with an organic compound layer including 2,2,6,6-tetramethylpiperidinoxiradical. The spin density of the organic compound layer 1 measured by ESR spectrum was 2.2×10²¹ spins/g at that time.

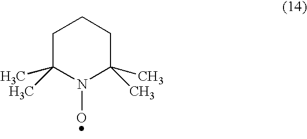

With the photoelectrochemical device obtained as above, in the case of sweeping the potential of the semiconductive electrode 5 as opposed to the lithium reference electrode in the range of 0 to 3.2V at the sweep rate of 100 mV/sec, the electric current was 0.1 mA/m² or less at every potential. Next, when the potential was swept while irradiating tungsten halogen light of 100 mW/cm² on the semiconductive electrode 5, a largest current flow was observed at about 3.0V. The current reached a maximum strength of 2.5 mA/cm². This result confirmed that the photoelectrochemical device was able to sense the presence of irradiating light.

### EXAMPLE 3

First, the radical polymerization of 2,2,6,6-tetramethylpiperidinemethacrylate was carried out. Then, the polymerization product was oxidized by m-chloroperbenzoic acid into poly-(2,2,6,6-tetramethylpiperidinoximethacrylate) radical (represented by formula 15 below). The obtained radical compound was a brown polymer solid with a number average molecular weight of 89000. The spin density of the radical compound measured by ESR spectrum was 2×10²¹ spins/g.

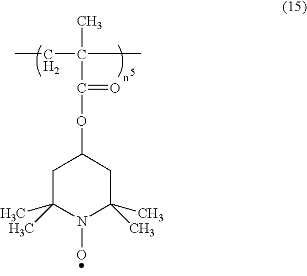

Subsequently, the organic compound layer 1 of 0.6 μm in thickness including the radical compound was formed on the semiconductive electrode 5 by means of spreading thereon a solution made by dissolving the radical compound in tetrahydrofuran in a concentration of 15 wt. % and evaporating the solvent of tetrahydrofuran.

On the organic compound layer 1, the electrolyte layer 6 of 10 μm in thickness was then formed with a gel electrolyte film, which consisted of vinylidene fluoride-hexafluoropropylene copolymer swelling in a mixed solvent of ethylene carbonate and diethyl carbonate (in a mass ratio of 1 to 1) including 1M of LiPF₆.

After that, an lithium superimposed copper foil of 25 μm in thickness was stacked as the counter electrode 4 on the electrolyte layer 6, and pressure was brought to bear thereon. Thus, there was obtained a photoelectrochemical device provided with an organic compound layer including the aforementioned radical compound.

With this photoelectrochemical device, in the case of sweeping the potential of the semiconductive electrode 5 as opposed to the counter electrode 4 of lithium superimposed copper foil in the range of 0 to 3.2V at the sweep rate of 100 mV/sec, the electric current was 0.1 mA/cm² or less at every potential. Next, when the potential was swept while irradiating tungsten halogen light of 100 mW/cm² on the semiconductive electrode 5, a largest current flow was observed at about 3.0V. The current reached a maximum of 2.5 mA/cm². This result confirmed that the photoelectrochemical device was able to sense the presence of irradiating light.

### EXAMPLE 4

First, a transparent conductive indium/tin oxide (ITO) film of 0.01 μm in thickness was deposited as the semiconducting layer 2 on the substrate 7 of 0.8 mm thick glass plate by means of sputtering, and thus forming the semiconductive electrode 5. Subsequently, patterning was performed to form the semiconductive electrode 5 into prescribed stripes in 10 mm width by using a hydrochloric aqueous solution.

Subsequently, the organic compound layer 1 of 0.8 μm in thickness including the aforementioned poly-(2,2,6,6-tetramethylpiperidinoximethacrylate) radical was formed on the semiconductive electrode 5. On the organic compound layer 1, the electrolyte layer 6 of 10 μm in thickness was formed with the gel electrolyte film like the one above. Then, a polyimide film having thereon the counter electrode 4 composed of lithium superimposed copper foil in 10 mm-wide stripes was stacked on the electrolyte layer 6 with the direction of the stripes being in right-angle alignment with the semiconductive electrode 5. Thus, there was obtained a photoelectrochemical device provided with a matrix of electrodes.

With this photoelectrochemical device, when tungsten halogen light of 100 mW/cm² was irradiated on part of the matrix semiconductive electrode 5 while applying a voltage of 3V to both the electrodes 4 and 5, a current flow of 1 mA/cm² or more was observed only at the part irradiated by the light. Next, having detached the electrodes from the photoelectrochemical device, parts of the organic compound layer 1 were cut off to measure the spin density by ESR spectrum. The spin density of the irradiated part was 10¹⁹ spins/g or less, while that of non-irradiated part was 2×10²¹ spins/g. This result confirmed that the photoelectrochemical device was able to write information by means of irradiating light.

### EXAMPLE 5

In this example, the photoelectrochemical device according to example 4, which was characterized by the organic compound layer including poly-(2,2,6,6-tetramethylpiperidinoximethacrylate) radical and a matrix of the electrodes, was employed. With the photoelectrochemical device, in the case of applying a voltage of 4.5V to part of the matrix semiconductive electrode 5, there was observed a change in hue of the organic compound layer 1 from brown to bronze. This result confirmed that the photoelectrochemical device was able to generate images by means of electric current.

Besides, parts of the organic compound layer 1 were cut off to measure the spin density by ESR spectrum. The spin density of the part where the voltage had been applied was 10¹⁹ spins/g or less, while that of part where the voltage had not been applied was 2×10²¹ spins/g. This result indicated that there was effected a change similar to that observed in example 4 in which a voltage of 3V was applied while irradiating the light.

### EXAMPLE 6

First, the photoelectrochemical device was manufactured after the same method in example 3. With this photoelectrochemical device, in the case of irradiating tungsten halogen light of 100 mW/cm² on the semiconductive electrode 5, a current of 0.8 mA/cm² flowed. This result confirmed that the photoelectrochemical device could be used as a photoelectric conversion element such as a photosensor and a solar cell.

### EXAMPLE 7

First, the photoelectrochemical device was manufactured after the same method in example 3. Then, the counter electrode 4 of lithium superimposed copper foil was connected via a diode to the semiconductive electrode 5 so that current flows from the electrode 4 to the electrode 5 in the forward direction. With this photoelectrochemical device, tungsten halogen light of 100 mW/cm² was irradiated on the semiconductive electrode 5 for five hours. After that, having formed short-circuit between the semiconductive electrode 5 and counter electrode 4, the photoelectrochemical device was made discharge at a current density of 0.1 mW/cm². During the discharge, the voltage remained more than 2.0V over a period of eight hours. This result confirmed that the photoelectrochemical device could be used as a storage cell or battery for storing electric energy generated by photoelectric conversion as well as a photoelectric conversion element.

In the process, the spin density of the organic compound layer 1 was measured on several occasions. The spin density was 10¹⁹ spins/g or less after five hours of light irradiation, while it had been 2×10²¹ spins/g in the initial stage. After the discharge, the spin density returned to 2×10²¹ spins/g. This result has shown that the poly-(2,2,6,6-tetramethylpiperidinoximethacrylate) radical included in the organic compound layer 1 undergoes chemical change and stores electric energy.

As set forth hereinabove, in accordance with the present invention, the organic compound generates the radical compound through at least electrochemical oxidation reaction or reduction reaction. With the combination of the organic compound and semiconductor, charge carriers (electrons/holes) generated by irradiating light on the semiconductor are involved in redox reaction of the organic compound and cause the generation/disappearance of the radical compound due to radical reaction. In the photoelectrochemical device of the present invention, the radical compound and organic compound that generates the radical compound serve as a redox pair, which increases the rate of reaction to the irradiating light. Moreover, the photoelectrochemical device is provided with excellent stability and reproducibility. Additionally, the photoelectrochemical device is simply constructed, and does not need the complicated semiconductor manufacturing process differently from conventional ones. Consequently, it is possible to manufacture a large stable photoelectrochemical device at low cost.

While the present invention has been described with reference to the particular illustrative examples, it is not to be restricted by those examples but only by the appended claims. It is to be appreciated that those skilled in the art can change or modify the examples without departing from the scope and spirit of the present invention.

What is claimed is:

1. A photoelectrochemical device comprising: an organic compound which generates a radical compound through electrochemical oxidation reaction and/or reduction reaction; and a semiconductor arranged in contact with the organic compound.

2. A photoelectrochemical device comprising: an organic compound which generates a radical compound having a spin density of 10²⁰ spins/g or more through electrochemical oxidation reaction and/or reduction reaction; and a semiconductor arranged in contact with the organic compound.

3. The photoelectrochemical device claimed in claim 1, wherein the radical compound is in a solid state at room temperature, 25±35° C.

4. The photoelectrochemical device claimed in claim 2, wherein the radical compound is in a solid state at room temperature, 25±35° C.

5. The photoelectrochemical device claimed in claim 1, wherein the organic compound is an organic polymer compound with the number average molecular weight ranging from 10³ to 10⁷.

6. The photoelectrochemical device claimed in claim 2, wherein the organic compound is an organic polymer compound with the number average molecular weight ranging from 10³ to 10⁷.

7. The photoelectrochemical device claimed in claim 3, wherein the organic compound is an organic polymer compound with the number average molecular weight ranging from 10³ to 10⁷.

8. The photoelectrochemical device claimed in claim 4, wherein the organic compound is an organic polymer compound with the number average molecular weight ranging from 10³ to 10⁷.

9. A photoelectrochemical device comprising:
a semiconductive electrode having a semiconducting layer;
an organic compound layer that is in contact with the semiconductive electrode, and generates a radical compound through electrochemical oxidation reaction and/or reduction reaction;
a counter electrode opposing to the semiconductive electrode; and
an electrolyte layer arranged between the organic compound layer and counter electrode.

10. The photoelectrochemical device claimed in claim 1, wherein irradiating light on the semiconductor effects an electrical, optical, or chemical change through electrochemical oxidation reaction and/or reduction reaction.

11. The photoelectrochemical device claimed in claim 2, wherein irradiating light on the semiconductor effects an electrical, optical, or chemical change through electrochemical oxidation reaction and/or reduction reaction.

12. The photoelectrochemical device claimed in claim 3, wherein irradiating light on the semiconductor effects an electrical, optical, or chemical change through electrochemical oxidation reaction and/or reduction reaction.

13. The photoelectrochemical device claimed in claim 5, wherein irradiating light on the semiconductor effects an electrical, optical, or chemical change through electrochemical oxidation reaction and/or reduction reaction.

14. The photoelectrochemical device claimed in claim 9, wherein irradiating light on the semiconducting layer effects an electrical, optical, or chemical change through electrochemical oxidation reaction and/or reduction reaction.
